(19) United States
(12) Patent Application Publication
(10) Pub. No.: US 2015/0282350 A1
(43) Pub. Date: Oct. 1, 2015

(54) Electronic Device With Cured Adhesive Screw Boss Mounting Structures

(71) Applicant: Apple Inc., Cupertino, CA (US)

(72) Inventors: Daniel L. McBroom, Leonard, TX (US); Michael McBroom, Leonard, TX (US)

(73) Assignee: Apple Inc., Cupertino, CA (US)

(21) Appl. No.: 14/242,542

(22) Filed: Apr. 1, 2014

(51) Int. Cl. H05K 5/02; H05K 5/04; H05K 5/00

(52) U.S. Cl. CPC H05K 5/0217; H05K 5/0017; H05K 5/04; H05K 5/0026

(57) ABSTRACT

Screw bosses may be attached to a support structure using screw boss support structures. The screw boss support structures may be formed from cured adhesive. An elastomeric mold may be pressed against a support structure such as a curved metal electronic device housing. While the mold is held in place, plastic screw bosses may be inserted partway into mold cavities. Liquid adhesive may then be injected into the mold cavities and cured to attach the screw bosses to the housing. Self-threading screws may be used to mount a printed circuit board to the screw bosses. The screw bosses may aligned with respect to a common vertical position so that a different amount of adhesive is present between each screw boss and the curved metal housing.

### BACKGROUND

This relates generally to electronic devices and, more particularly, to bosses for mounting items within electronic device housings.

Electronic devices include printed circuit boards and other structures that are mounted within housings. In some arrangements, components are held in place using internal mounting structures such as clips or grooves. To maximize ease of assembly and the possibility of rework, it may be desirable to mount components using screws. Housings can be provided with screw bosses to receive mounting screws, but fabrication challenges such as machining and molding issues may make it difficult to accurately form screw bosses in desired locations.

It would therefore be desirable to be able to provide improved techniques for forming electronic devices with screw bosses.

### SUMMARY

Screw bosses may be attached to a support structure using screw boss support structures. The screw boss support structures may be formed from cured adhesive such as cured epoxy. The support structure to which the screw bosses are attached may be a metal housing such as a curved electronic device housing or other structure.

During formation of the screw boss support structures, an elastomeric mold may be pressed against the support structure. For example, a planar elastomeric sheet with mold cavities for forming the screw boss support structures may be pressed against the inner surface of a metal electronic device housing using a press.

While the mold is being held in place, plastic screw bosses may be inserted partway into the mold cavities using a boss dispensing system. Liquid adhesive may then be injected into the mold cavities and cured to attach the screw bosses to the support structure. While the liquid adhesive is being injected into the mold cavities, the screw bosses may be registered to a registration surface that is independent of the metal housing or other support structure to which the screw bosses are being mounted. This allows the screw bosses to be aligned with respect to a common vertical position so that a different amount of adhesive may be formed between each screw boss and the metal housing, thereby accommodating curved housing shapes.

Threaded fasteners such as self-threading screws may be used to mount printed circuit boards or other structures to the screw bosses.

### BRIEF DESCRIPTION OF THE DRAWINGS

FIG. 1 is a perspective view of an illustrative electronic device such as a laptop computer in accordance with an embodiment.

FIG. 2 is a perspective view of an illustrative electronic device such as a handheld electronic device in accordance with an embodiment.

FIG. 3 is a perspective view of an illustrative electronic device such as a tablet computer in accordance with an embodiment.

FIG. 4 is a perspective view of an illustrative electronic device such as a computer or other equipment with a display in accordance with an embodiment.

FIG. 5 is a diagram of an illustrative support structure such as a portion of an electronic device housing in accordance with an embodiment.

FIG. 6 is a cross-sectional side view of an illustrative elastomeric mold in contact with the support structure of FIG. 5 in accordance with an embodiment.

FIG. 7 is a cross-sectional side view of art illustrative set of screw bosses that have been inserted into mold cavities in the elastomeric mold of FIG. 6 in accordance with an embodiment.

FIG. 8 is a cross-sectional side view of the support structure of FIG. 5 following attachment of the screw bosses of FIG. 6 by curing adhesive in the mold cavities of FIG. 7 in accordance with an embodiment.

FIG. 9 is a cross-sectional side view of the support structure of FIG. 8 after using screws to mount a structure such as a printed circuit board to the screw bosses on the support structure in accordance with an embodiment.

FIG. 10 is a perspective view of an illustrative self-threading screw and associated unthreaded screw boss tube in accordance with an embodiment.

FIG. 11 is a diagram of an illustrative system for mounting screw bosses on a support structure such as a device housing in accordance with an embodiment.

FIG. 12 is a diagram of a portion of the illustrative system of FIG. 11 showing how bosses may be loaded using a hopper-based boss distribution system with an electronically controlled gate and showing how heaters may be used to facilitate adhesive curing in accordance with an embodiment.

FIG. 13 is a cross-sectional side view of a portion of a system for controlling the position of screw boss tubes during adhesive curing in a system of the type shown in FIG. 11 in accordance with an embodiment.

FIG. 14 is a cross-sectional side view of a support structure such as an electronic device housing in which a structure has been mounted using screw bosses in accordance with an embodiment.

FIG. 15 is a cross-sectional side view of a support structure such as an electronic device housing in which a printed circuit board and a device structure such as a speaker, power supply, or other component have been mounted using screw bosses in accordance with an embodiment.

FIG. 16 is a flow chart of illustrative steps involved in mounting structures using screw bosses and threaded fasteners when forming an item such as an electronic device in accordance with an embodiment.

### DETAILED DESCRIPTION

A support structure such as an electronic device housing may be provided with mounting structures such as screw bosses to facilitate the mounting of printed circuit boards, electronic components, and other structures. The screw bosses may be attached an electronic device housing or other support structure using a polymer such as a thermoset polymer adhesive.

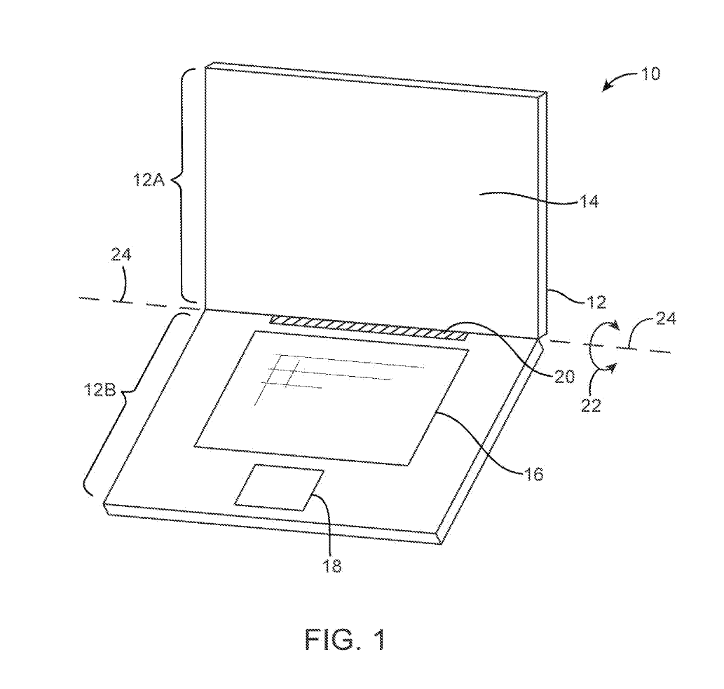

Illustrative electronic devices that may be provided with screws bosses are shown in FIGS. 1, 2, 3, and 4.

Electronic device 10 of FIG. 1 has the shape of a laptop computer and has upper housing 12A and lower housing 12B with components such is keyboard 16 and touchpad 18. Device 10 has hinge structures 20 (sometimes referred to as a clutch barrel) to allow upper housing 12A to rotate in directions 22 about rotational axis 24 relative to lower housing 12B. Display 14 is mounted in housing 12A. Upper housing 12A, which may sometimes be referred to as a display housing or lid, is placed in a closed position by rotating upper housing 12A towards lower housing 12B about rotational axis 24.

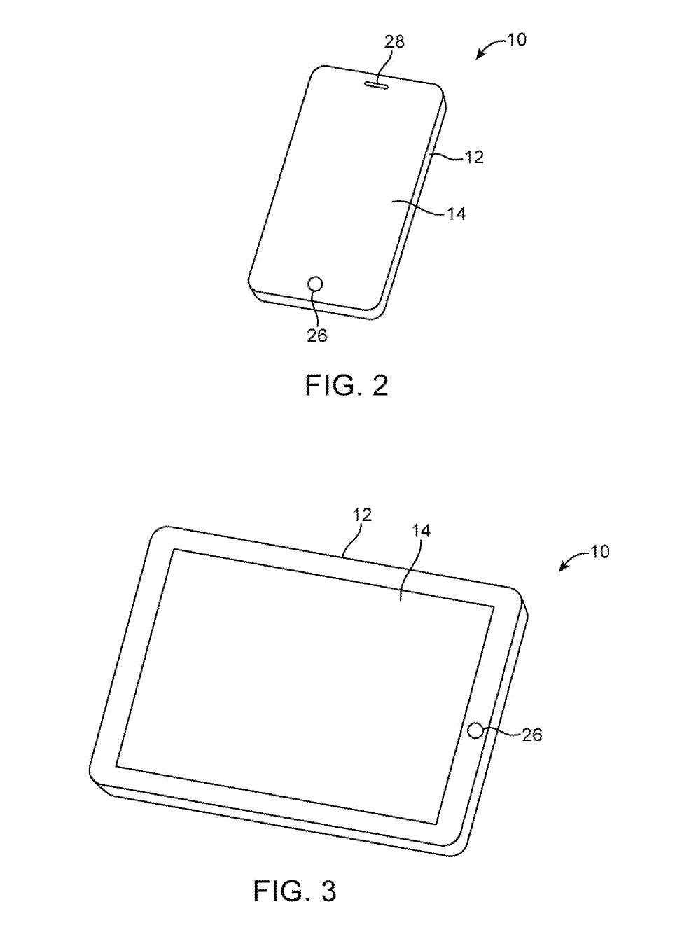

FIG. 2 shows an illustrative configuration for electronic device 10 based on a handheld device such as a cellular telephone, music player, gaming device, navigation unit, or other compact device. In this type of configuration for device 10, device 10 has opposing front and rear surfaces. The rear surface of device 10 may be formed from a planar portion of housing 12. Display 14 forms the front surface of device 10. Display 14 may have an outermost layer that includes openings for components such as button 26 and speaker port 28.

In the example of FIG. 3, electronic device 10 is a tablet computer. In electronic device 10 of FIG. 3, device 10 has opposing planar front and rear surfaces. The rear surface of device 10 is formed from a planar rear wall portion of housing 12. Curved or planar sidewalls may run around the periphery of the planar rear wall and may extend vertically upwards. Display 14 is mounted on the front surface of device 10 in housing 12. As shown in FIG. 3, display 14 has an outermost layer with an opening to accommodate button 26.

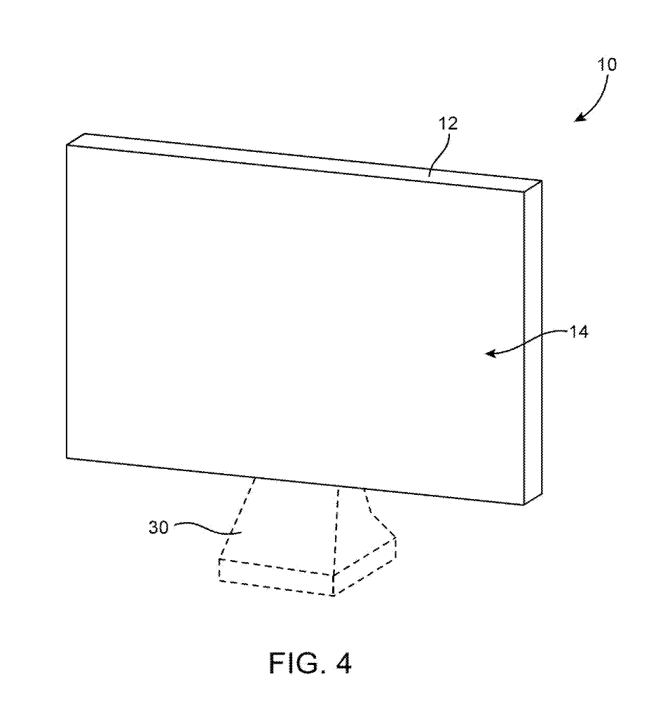

FIG. 4 shows an illustrative configuration for electronic device 10 in which device 10 is a computer display, a computer that has an integrated computer display, or a television. Display 14 is mounted on a front face of device 10 in housing 12. With this type of arrangement, housing 12 for device 10 may be mounted on a wall or may have an optional structure such as support stand 30 to support device 10 on a flat surface such as a tabletop.

An electronic device such as electronic device 10 of FIGS, 1, 2, 3, and 4, may, in general, be a computing device such as a laptop computer, a computer monitor containing an embedded computer, a tablet computer, a cellular telephone, a media player, or other handheld or portable electronic device, a smaller device such as a wrist-watch device, a pendant device, a headphone or earpiece device, or other wearable or miniature device, a television, a computer display that does not contain an embedded computer, a gaming device, a navigation device, an embedded system such as a system in which electronic equipment is mounted in a kiosk or automobile, equipment that implements the functionality of two or more of these devices, or other electronic equipment. The examples of FIGS. 1, 2, 3, and 4 are merely illustrative.

Device 10 may include a display such as display 14. Display 14 may be mounted in housing 12. Housing 12, which may sometimes be referred to as an enclosure or case, may be formed of plastic, glass, ceramics, fiber composites, metal (e.g., stainless steel, aluminum, etc.), other suitable materials, or a combination of any two or more of these materials. Housing 12 may be formed using a unibody configuration in which some or all of housing 12 is machined or molded as a single structure or may be formed using multiple structures (e.g., an internal frame structure, one or more structures that form exterior housing surfaces, etc.).

Display 14 may be a touch screen display that incorporates a layer of conductive capacitive touch sensor electrodes or other touch sensor components (e.g., resistive touch sensor components, acoustic touch sensor components, force-based touch sensor components, light-based touch sensor components, etc.) or may be a display that is not touch-sensitive. Capacitive touch screen electrodes may be formed from an array of indium tin oxide pads or other transparent conductive structures.

Display 14 may include an array of display pixels formed from liquid crystal display (LCD) components, an array of electrophoretic display pixels, an array of plasma display pixels, an array of organic light-emitting diode display pixels, an array of electrowetting display pixels, or display pixels based on other display technologies.

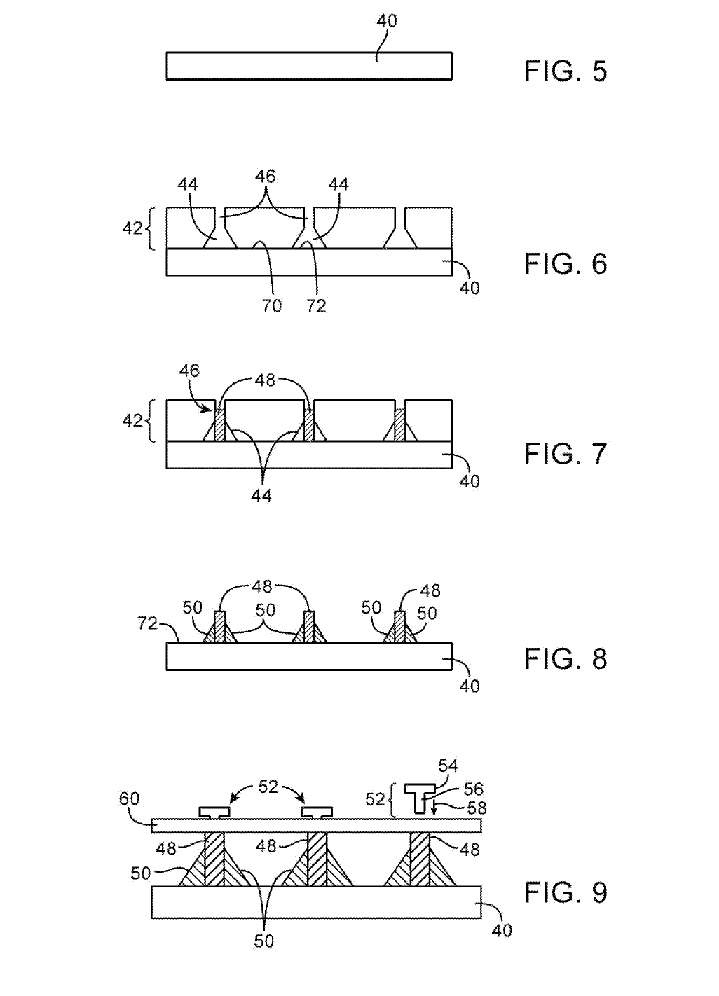

FIGS. 5, 6, 7, 8, and 9 are cross-sectional side views of a support structure to which screw bosses are being attached to facilitate mounting of other structures in an electronic device such as electronic device 10 of FIGS. 1, 2, 3, or 4. FIG. 5 is a cross-sectional side view of an illustrative support structure before screw bosses have been attached. Support structure 40 may be part of housing 12 in device 10 or other suitable structure. As an example, support structure 40 may be a metal device housing for device 10 or may be a device housing formed from other materials (e.g., plastic, fiber composite materials such as carbon fiber materials, metal, glass, ceramic, other materials, or combinations of these materials). The surface of support structure 40 may be coated with a layer of plastic, an oxide layer (e.g., an aluminum oxide anodized layer on an aluminum housing), paint, or other materials. If desired, support structure 40 may be an internal structure in device 10 (e.g., a support bracket, a housing frame, a midplate housing member, part of a printed circuit board, part of a connector, or part of an electronic component, or other internal electronic device structures). Support structure 40 may be planar, may be curved, may have a combination of curved and flat surfaces, or may have other suitable shapes. Configurations in which support structure 40 is a curved metal electronic device housing structure (e.g., a curved metal rear housing wall for device 10 of FIG. 4 or other devices of FIGS. 1, 2, 3, or 4) are sometimes described herein as an example. This is, however, merely illustrative. Support structure 40 of FIG. 5 may be any suitable structure to which it is desired to mount other structures.

Screw bosses may be mounted to support structure 40 using screw boss attachment structures. The boss attachment structures may be formed from a polymer or other suitable material. As an example, the boss attachment structures may be formed from a thermoset plastic such as epoxy adhesive or other thermoset adhesive. The adhesive may initially be provided in an uncured liquid form. While in its uncured liquid form, the adhesive may be placed into a desired shape using a mold such as mold 42 of FIG. 6. As shown in FIG. 6, mold 42 may have openings that form mold cavities such as cavities 44. Mold 42 may be formed from an elastomer such as silicone or other material. During molding operations, lower surface 70 of mold 42 may be pressed against upper surface 72 of support structure 40. The elastomeric material of mold 42 may stretch slightly to form a seal against surface 72, thereby helping to retain adhesive within cavities 44.

Before injecting liquid adhesive into cavities 44, bosses 48 may be inserted into mold 42. As shown in FIG. 7, mold 42 may have openings such as openings 46 that receive bosses 48. Bosses 48 may have the shape of hollow tubes or other suitable shapes. Bosses 48 may be formed from plastic (e.g., hollow plastic tubes), metal, fiber-composites, other materials, or combinations of these materials. Configurations in which bosses 48 are formed from elongated plastic structures such as hollow tubes are sometimes described herein as an example.

As shown in FIG. 7, bosses 48 may be inserted partway into cavities 44, so that an upper portion of each boss 48 protrudes out of cavity 44 (i.e., so that a part of each boss 48 resides in opening 46 instead of cavity 44). This prevents the upper end of boss 48 from being covered with adhesive during adhesive molding operations, thereby ensuring that boss 48 has a clean surface for supporting the structures being mounted to boss 48.

After inserting bosses 48 partway into cavities 44 as shown in FIG. 7, adhesive may be introduced to cavities 44 and cured. The shape of cavities 44 defines the shape of cured adhesive. Mold 42 may be removed after the adhesive has been cured. As shown in FIG. 8, cured adhesive 50 forms boss attachment structures that attach bosses 48 to support structure 40. In the example of FIG. 8, each boss attachment structure 50 has the shape of an inverted cone. Bosses 48 protrude from the narrow upper portion of each cone. The use of a shape such as a cone shape in which the bottom of boss attachment structure 50 near surface 72 is wider than the top of the boss attachment structure 50 from which boss 48 protrudes may facilitate removal of mold 42 from boss attachment structures 50 following curing of the adhesive that forms boss attachment structures 50. Other shapes (e.g., other shapes in which the lower portions are wider than the upper portions) may be used for boss attachment structures 50 if desired. The adhesive of boss attachment structures 50 adheres to surface 72 of support structure 40. Support structure 40 and/or bosses 48 may, if desired, be provided with is rough surface texture, protruding engagement features that engage molded adhesive, or other adhesion promotion features to facilitate the formation of a strong bond between boss attachment structure 50 and support structure 40 (and bosses 48). Surface 72 may be, for example, the inner surface of a metal housing such as housing 12 of device 10.

After bosses 48 have been attached to support structure 40 using boss attachment structures 50, bosses 48 may be used in mounting structures within device 10. For example, bosses 48 may receive threaded fasteners such as screws 52. Screws 52 may have heads 54 and shafts 56. Screws 52 may be screwed into bosses 48 by rotating heads 54 and thereby rotating screws 52 about shafts 56. Screws 52 may be used to secure structure 60 to support structure 40. Structure 60 may be a printed circuit board, an electronic component such as a speaker or power supply, an internal housing structure such as a support bracket or other piece of metal or plastic, or other electronic device structure. In the illustrative configuration of FIG. 9, multiple screws 52 have been used to screw a planar structure 60 such as a printed circuit board to bosses 48, thereby securing planar structure 60 to support structure 40. Other configurations may be used if desired. The configuration of FIG. 9 is presented as an example.

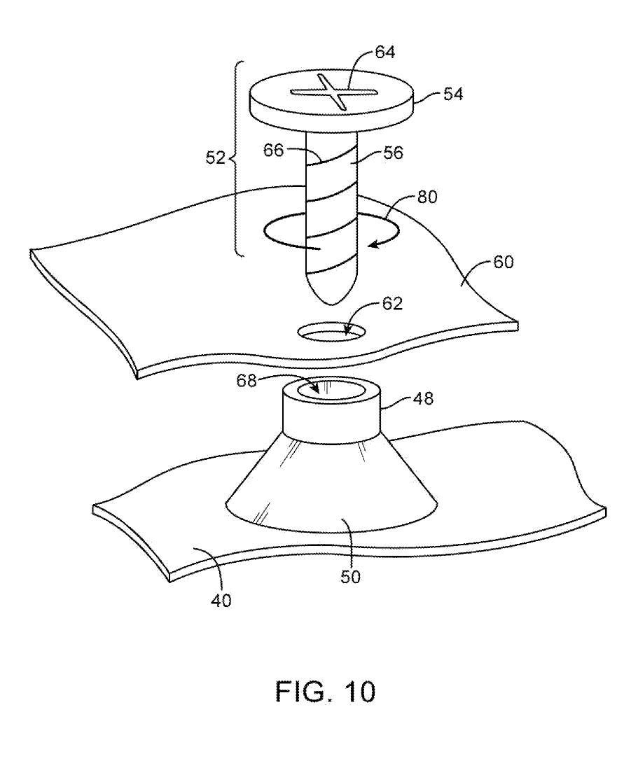

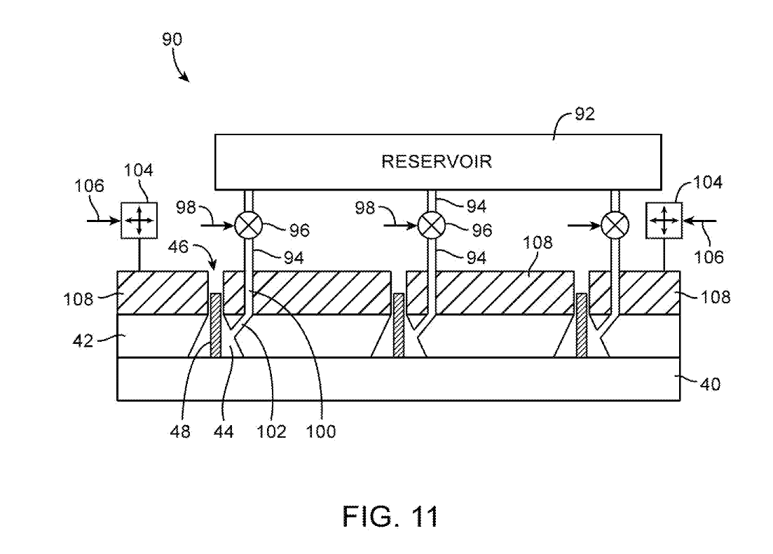

Bosses 48 may be threaded or unthreaded. With one suitable arrangement, bosses 48 are formed from hollow tubes of plastic or soft metal that are initially unthreaded. Screws 52 may be self-threading metal screws that can form threads within the soft inner surfaces of the hollow tubes. This type of configuration is shown in the perspective view of FIG. 10. In the arrangement of FIG. 10, screw boss 48 has been mounted to inner surface 72 of support structure 40 using cured adhesive that forms boss support structure 50. Boss 48 has a hollow tube shape with an opening such as unthreaded cylindrical opening 68. Cylindrical opening 68 runs along longitudinal axis of boss 48 and has an inner diameter that is suitable for engaging threads 66 on shaft 56 of screw 52. Screw 52 may be a self-threading threaded fastener such as a self-threading screw. Head 54 of screw 52 may have flat sides or engagement features such as features 64 for engaging a rotating screwdriver bit that rotates screw 52. When screw 52 is rotated in direction 80, threads 66 on shaft 56 will engage the inner walls of cylindrical openings 68 and will drive screw 52 into boss 48 while forming mating threads in boss 48. If desired, boss 48 may be pre-threaded.

Structure 60 (e.g., a printed circuit board, electronic component, or other structure that is being mounted to support structure 40) may have slots, holes, or other openings to facilitate mounting to boss 48. For example, structure 60 may have screw holes such as screw hole 62 that each receive a respective screw shaft such as shaft 56.

FIG. 11 is a diagram of illustrative equipment that may be used in mounting structures to a support such as support 40 of FIG. 10 using screw bosses such as screw bosses 48. As shown in FIG. 11, equipment 90 may include adhesive reservoir 92. Tubing such as tubing 94 may be used to dispense liquid adhesive from reservoir 92. Valves such as valves 96 may be interposed in the conduits formed from tubing 94 to regulate the flow of adhesive from reservoir 92 into cavities 44. The operation of valves 96 may be controlled using control signals supplied on control inputs 98. Equipment 90 may have a mold support structure such as plate 108. Plate 108, which may sometimes be referred to as a press structure, may be formed from plastic, metal, or other materials.

As shown in FIG. 11, the fluid paths formed by tubing 94 may be coupled to fluid paths formed from openings 100 in plate 108. The fluid paths formed from openings 100, in turn, may be coupled to fluid paths formed form openings 102 in mold 42. The fluid paths between reservoir 92 and cavities 44 may be used to inject liquid adhesive into cavities 44 to form boss support structures that support bosses 48. Bosses 48 may be inserted into cavities 44 using openings such as openings 46 in plate 108 and mold 42.

Mold 42 may be pressed against the surface of support structure 42 using positioning equipment such as positioners 104. Positioners 104 may be computer-controlled positioners that receive control signals via control inputs 106.

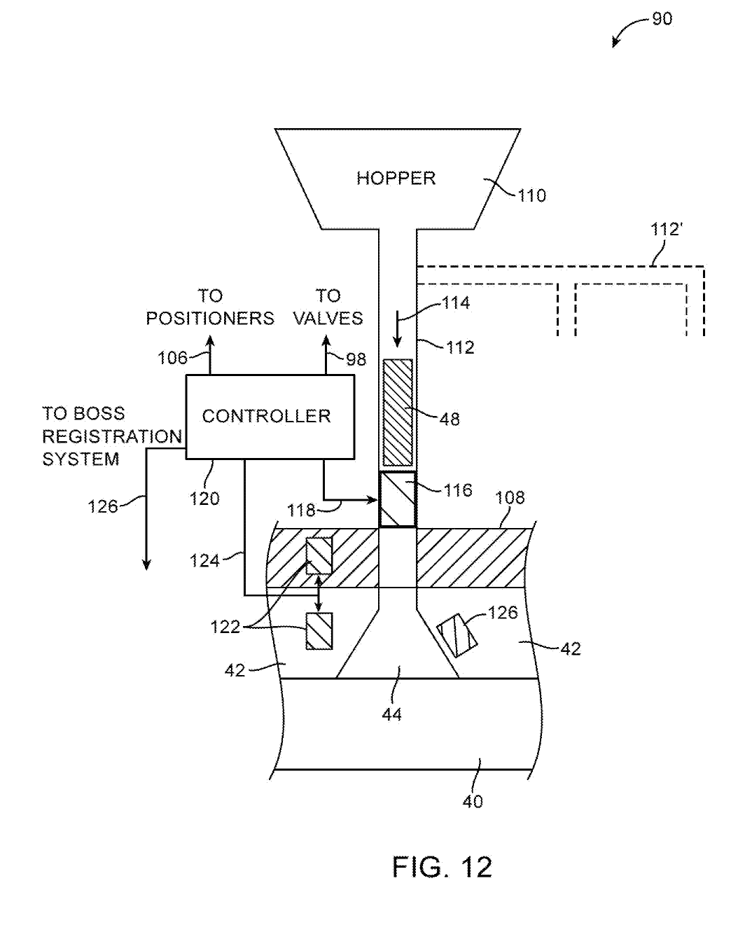

Equipment 90 may have a boss dispensing system that delivers bosses 48 to cavities 44 prior to injecting adhesive into cavities 44. Boss dispensing components that may be incorporated into equipment 90 to supply bosses 48 to cavities 44 are shown in FIG. 12. As shown in FIG. 12, equipment 90 may include a boss storage structure such as hopper 110. Tubing 112 or other structures may form a boss dispensing path that supplies bosses 48 to respective cavities 44 in mold 42. Tubing 112 may have portions such as portions 112′ that allow multiple bosses 48 to be provided to multiple respective cavities 44 in mold 42. Bosses 48 may be fed in downwards direction 114 using gravity, may be delivered to cavities 44 with pneumatic assistance, may be mechanically fed into tubing 112 and/or cavities 44 (e.g., using a screw-shaped dispenser), or may otherwise be moved from hopper 110 to cavities 44. If desired, control structures such as computer-controlled gates 116 may be used in regulating the distribution of bosses 48 to cavities 44. Each gate 116 in equipment 90 may have a respective control input 118 that receives control signals from controller 120 or other computing equipment in system 90. The control signals direct a mechanical shutter or other component in gate 116 to open and close, thereby regulating the flow of bosses 48.

Heating elements such as illustrative heating elements 122 may be included in equipment 90. Heating elements such as elements 122 may be mounted in cavities within mold 42, may be mounted within cavities or recesses in plate 108, may be mounted to the upper surface of plate 108, may be mounted within a fixture that holds support structure 40, and/or may otherwise be incorporated into equipment 90. Control signals from controller 120 may be supplied to heaters 122 using control paths 124. The control signals may regulate the amount of heat produced by heaters 122. The heat from heaters 122 may be used to facilitate curing of adhesive in cavities 44. If desired, light for facilitating the curing of adhesive may be introduced into cavity 44 using a light source such as computer-controlled light source 126. Light source 126 may be an ultraviolet lamp or other light source that emits light in response to control signals from controller 120. The light from light source 126 may be introduced into cavity 44 through a clear wall portion of mold 42 (e.g., in a configuration in which some or all of mold 42 is formed farm a transparent polymer). Other techniques for curing adhesive in cavity 44 to secure bosses 48 may be used if desired. The use of heat and/or light to cure liquid thermoset adhesive is merely illustrative.

Controller 120 may supply positioner control signals on path 106 for controlling positioners 104 of FIG. 11. Controller 120 may supply adhesive flow control commands on 98 to control valves 96 of FIG. 11. A boss positioning system that controls the relative position between bosses 48 and appropriate structures in system 90 may be controlled by controller 120 using signals supplied to control path 126.

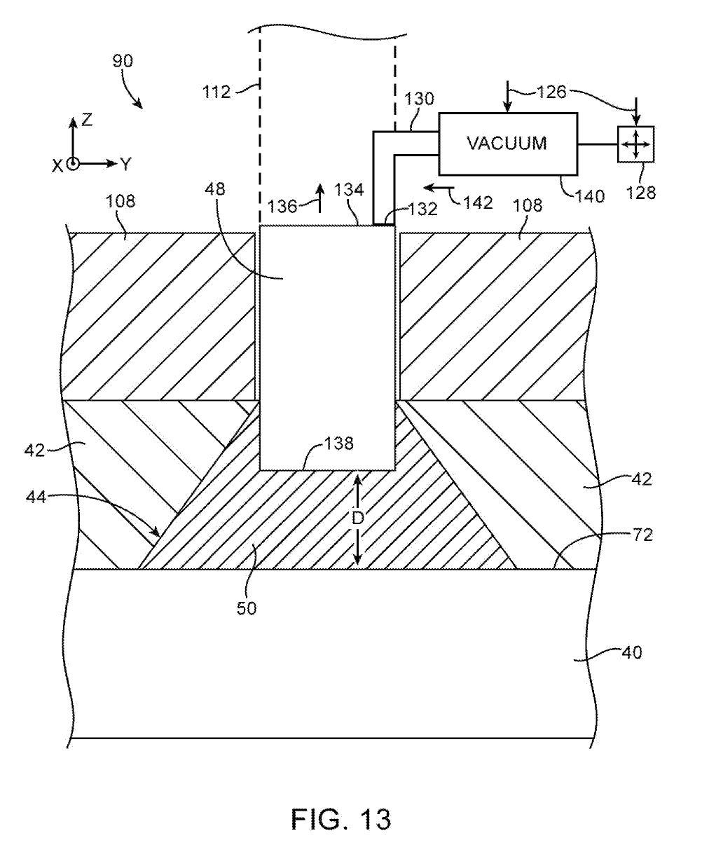

An illustrative boss positioning system (sometimes referred to as a boss registration system) that may be used in equipment 90 to control the position of bosses 48 during adhesive curing operations is shown in FIG. 13. In some situations, bosses 48 may be dispensed so that the lower surfaces of the bosses rest on upper surface 72 of support structure 40. It may be desirable in other situations to register the positions of bosses 48 to structures in equipment 90. In a configuration of the type shown in FIG. 13, for example, equipment such as computer-controlled vacuum source 140 and computer-controlled positioner 128 may be used in maintaining boss 48 in a desired position relative to a registration surface in equipment 90 during adhesive curing operations.

As shown in FIG. 13, vacuum source 140 may be coupled to tubing 130. Tubing 130 or other pathway for vacuum may be placed above boss 48. For example, positioner 128 may move tubing 130 in direction 142 after boss 48 has been inserted partway into cavity 44. Vacuum source 140 may then be used to supply vacuum to tubing 130. Due to the position of tubing 130 above the edge of boss 48, boss 48 will be drawn upwards in direction 136 by the vacuum from source 140. Boss 48 will travel upwards in direction 136 until upper surface 134 of boss 48 comes into contact with opposing lower surface 132 of tubing 130. The vacuum from vacuum source 140 may be used to hold boss 48 in this position. Surface 132 serves to register the position of boss 48. Accordingly, surfaces such as illustrative surface 132 may sometimes be referred to as boss registration surfaces. Boss registration surfaces in equipment 90 may be formed from tubing 130, from portions of plate 108, from portions of mold 42, from other structures attached to mold 42 and/or plate 108, or from other suitable registration structures. Registration may be performed along one or more dimensions (i.e., along the X-axis, Y-axis, and/or Z-axis of FIG. 13).

Using boss registration structures in equipment 90 (e.g., tubing 130 or other structures with boss registration surfaces that serve as one or more reference surface), the positions of bosses 48 may be determined relative to equipment 90 (e.g., relative to plate 108, mold 42, etc.). The position of equipment 90 in space (i.e., the position of plate 108, mold 42, and other structures in equipment 90) is known relative to axes X, Y, and Z. The absolute positions of the boss registration structures (e.g., tubing 130 and boss registration surface 132 in the FIG. 13 example) are therefore known. As a result, the equipment of FIG. 13 may be used to maintain bosses 48 in a known desired position during the formation of boss support structures 50. There may be uncertainties in the shape of surface 72 on support structure 40. By registering each boss 48 that is being attached to support structure 40 to a common reference that is independent of surface 72, upper surfaces 134 of all of bosses 48 (and, if desired, other portions of bosses 48) will be aligned with respect to absolute position X, Y, Z.

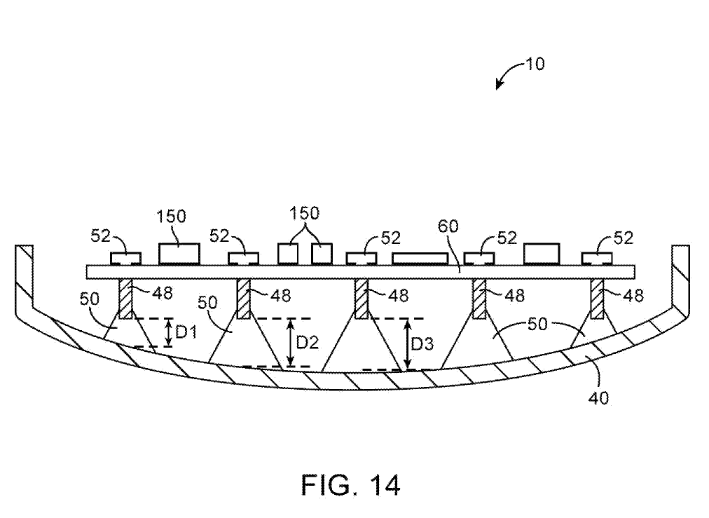

While bosses 48 are being maintained in a known position, adhesive may be injected into cavities 44 and cured to attach bosses 48 to support structure 40 and thereby permanently establish the positions of bosses 48 relative to support structure 40. In the example of FIG. 13, lower surface 138 of boss 48 is separated by a distance D from surface 72 of support structure 40. By positioning bosses 48 in known positions, the relative positions between bosses 48 may be accurately established. For example, upper surfaces 134 of all bosses 48 may be aligned with each other, even if each boss 48 is spaced by a different distance D from surface 72 and each boss 48 is therefore separated from surface 72 by a different amount of adhesive. This allows a structure such as a printed circuit board or other structure 60 to be mounted to upper surfaces 134 without bending, as shown in FIG. 14. In the example of FIG. 14, there are five bosses 48 that have been attached to support structure 40 using five respective boss attachment structures 50. Spacings D vary between bosses 48 and inner curved surface 72 of support structure 40 (e.g., the curved inner surface of a curved metal housing wall for device 10, etc.).

Surface 72 may curve, as an example, due to the curved interior shape of housing 12 (e.g., structure 40 may be housing 12), leading to different respective boss-to-housing spacings such as spacings D1, D2, and D3. In the FIG. 14 example, structure 40 has a curved inner surface, but printed circuit board 60 is planar. During the formation of boss support structures 50, equipment 90 registers the positions of bosses 48 relative to a known boss position registration surface in equipment 90. The bosses are therefore aligned to a common vertical position, allowing a flat structure such as planar printed circuit board 60 to be mounted to the upper surfaces of bosses 48 using screws 52. Because support 40 curves, different amounts of adhesive are formed under each boss 48, but the upper surfaces of bosses 48 are all aligned with the mating lower surface of printed circuit board 60, so printed circuit board 60 is not bent when screws 52 are used to attach printed circuit board 60 to bosses 48.

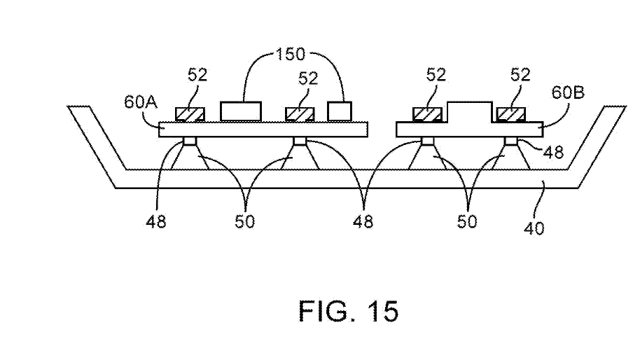

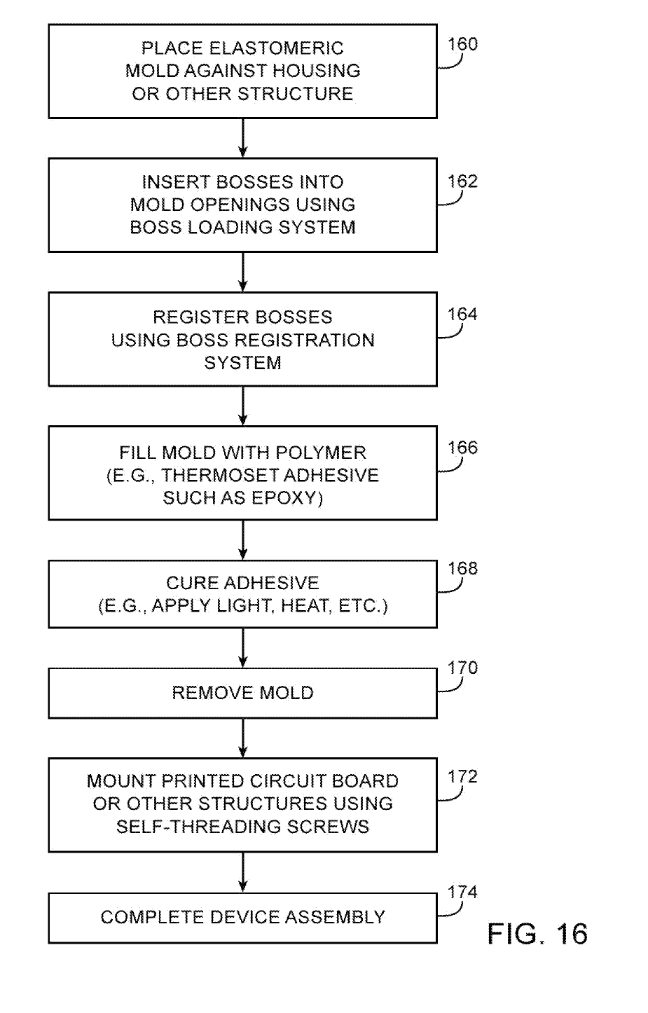

As shown in FIG. 14, electrical components 150 may be mounted to structure 60 (e.g., structure 60 may be a printed circuit substrate such as a rigid printed circuit board substrate formed from fiberglass-filled epoxy or other rigid printed circuit board material or such as a flexible printed circuit substrate of polyimide or other flexible polymer layer). Structures 60 may also include non-printed circuit structures, as shown in FIG. 15. In the example of FIG. 15, two different structures have been mounted to support structure 40 using bosses 48—structure 60A (e.g., a printed circuit board) and structure 60B. Structure 60B may be a structure other than a printed circuit board. As an example, structure 60B may be a speaker or other audio component, a power supply or other electrical component, a connector, a switch, a sensor, a button, a bracket or other support structure for an electrical component, an internal housing structure, or any other metal member, plastic member, or structure in device 10.

FIG. 16 is a flow chart of illustrative steps involved in fanning electronic devices or other assemblies using boss attachment techniques based on adhesive boss attachment structures. At step 160, controller 120 may use positioners 104 and plate 108 to press mold 42 against surface 72 of support structure 40, thereby forming sealed cavities 44. At step 162, controller 120 may direct the boss distribution equipment of FIG. 12 such as gate 116 to insert a boss into each cavity 44. Each boss may extend partly into a respective cavity and may have a portion that extends outside of that cavity.

Controller 120 may direct a boss position control system such as the boss registration system of FIG. 13 to place bosses 48 in desired positions at step 164. Bosses 48 may, for example, be positioned in alignment with each other (i.e., bosses 48 may be registered with respect to a common registration structure such as a planar registration surface so that the upper surfaces of all of bosses 48 are in alignment, with each other, regardless of the exact positions of the bottom surfaces of bosses 48 relative to support structure surface 74).

At step 166, mold 42 may be filled with adhesive. For example, controller 120 may direct valves 96 to dispense liquid adhesive such as uncured liquid epoxy or other uncured liquid thermoset adhesive into cavities 44.

At step 168, controller 120 may direct adhesive curing equipment such as heating equipment 122 and/or light curing equipment 126 to cure the dispensed liquid adhesive. If desired, the adhesive may be cured at room temperature without applying heat or light from source 126.

Following curing of the liquid epoxy or other adhesive to form boss support structures 50 (e.g., cured thermoset adhesive boss support structures), mold 42 may be removed from support structure 40 (i.e., controller 120 may use positioners 104 to move mold 42 away from structure 40 during the operations of step 170).

At step 172, screws 52 may be rotated to drive threaded fasteners such as screws 52 into bosses 48. Screws 52 may be self-threading screws that create threads in unthreaded openings in bosses 48 or bosses 48 may be pre-threaded. During the operations of step 172, screw shafts 56 may pass through screw holes in structures to be mounted to bosses 48 such as illustrative screw shaft opening 62 in structure 60 of FIG. 10. The heads 54 of screws 52 hold structure 60 against the upper surfaces of bosses 48, thereby mounting structure 60 to bosses 48 and support structure 40. Controller 120 may control equipment that inserts screws 52 into bosses 48 or screws 52 may be manually inserted into bosses 48.

During the operations of step 174, device assembly may be completed. For example, additional structures such as structure 60 may be mounted to other regions of support structure 40, components may be attached to structure 60 and/or support structure 40, display 14 and other structures in device 10 may be mounted in support structure 40 (e.g., housing 12), etc. A user may then use device 10.

The foregoing is merely illustrative and various modifications can be made by those skilled in the art without departing from the scope and spirit of the described embodiments. The foregoing embodiments may be implemented individually or in any combination.

What is claimed is:

1. Apparatus, comprising:
a first structure;
a screw boss;
a cured thermoset adhesive boss support structure that attaches the screw boss to the first structure;
a second structure; and
a screw that is screwed into the screw boss and that attaches the second structure to the screw boss.

2. The apparatus defined in claim 1 wherein the first structure comprises metal.

3. The apparatus defined in claim 2 wherein the screw boss comprises plastic.

4. The apparatus defined in claim 3 wherein the second structure comprises a printed circuit board.

5. The apparatus defined in claim 4 wherein the printed circuit board has a screw hole that receives the screw.

6. The apparatus defined in claim 5 wherein the screw boss comprises a plastic tube that has an upper surface that supports the printed circuit board and that has an opposing lower surface and wherein a portion of the cured thermoset adhesive boss support structure is between the lower surface and the first structure.

7. The apparatus defined in claim 6 wherein the first structure comprises a metal electronic device housing.

8. The apparatus defined in claim 4 wherein the second structure comprises an electrical component.

9. The apparatus defined in claim 4 wherein the first structure comprises a curved metal electronic device housing wall.

10. The apparatus defined in claim 4 wherein the screw comprises a self-threading screw that forms threads in the screw boss.

11. The apparatus defined in claim 1 wherein the screw boss comprises a plastic tube and wherein the first structure comprises metal.

12. The apparatus defined in claim 11 wherein the cured thermoset adhesive boss support structure comprises epoxy.

13. An electronic device, comprising:
a metal housing;
a plurality of cured thermoset adhesive screw boss support structures;
a plurality of screw bosses each of which is attached to the metal housing by a respective one of the cured thermoset adhesive screw boss support structures;
a printed circuit board; and
threaded fasteners that screw into the screw bosses and attach the printed circuit board to the screw bosses.

14. The electronic device defined in claim 13 wherein each strews boss is separated from the metal housing by a different distance and wherein a portion of each of the cured thermoset adhesive screw boss support structures is interposed between a respective one of the screw bosses and the metal housing.

15. The electronic device defined in claim 14 further comprising a display mounted in the metal housing, wherein the display forms a front surface of the electronic device and wherein the metal housing forms a rear surface of the electronic device.

16. The electronic device defined in claim 15 wherein the metal housing has a cured housing wall to which the eared thermoset adhesive screw boss support structures are attached.

17. The electronic device defined in claim 16 wherein the threaded fasteners comprise self-threading screws and wherein the screw bosses comprise plastic tubes.

18. A method of mounting a structure to a metal electronic device housing, comprising:
holding a plurality of plastic screw bosses in desired position;
while holding the plastic screw bosses in their desired positions, injecting uncured liquid thermoset adhesive into mold cavities in a mold; and
after injecting the uncured liquid thermoset adhesive into the mold cavities, curing the uncured liquid thermoset adhesive to form cured thermoset adhesive screw boss support structure that attach the screw bosses to the metal electronic device housing.

19. The method defined in claim 18 wherein the mold comprises an elastomeric mold, the method further comprising:
pressing the elastomeric mold against an inner surface of the metal electronic device housing before injecting the uncured liquid thermoset adhesive into the mold cavities.

20. The method defined in claim 19 further comprising:
screwing self-threading screws into the plastic screw bosses to attach the structure to the metal electronic device housing.
